(19) United States
(12) Patent Application Publication
(10) Pub. No.: US 2026/0182210 A1
(43) Pub. Date: Jun. 25, 2026

(54) ARRAY SUBSTRATE AND DISPLAY DEVICE

(71) Applicants: Yunnan Invensight Optoelectronics Technology Co., Ltd., Kunming, Yunnan (CN); BOE Technology Group Co., Ltd., Beijing (CN); Beijing BOE Technology Development Co., Ltd., Beijing (CN)

(72) Inventors: Chao Pu, Beijing (CN); Dacheng Zhang, Beijing (CN); Qingshan Shan, Beijing (CN); Xiaochuan Chen, Beijing (CN); Yinhu Huang, Beijing (CN); Shengji Yang, Beijing (CN); Pengcheng Lu, Beijing (CN); Zhao Ma, Beijing (CN); Liuzeming Qu, Beijing (CN); Qi Su, Beijing (CN); Zhuoyang Xie, Beijing (CN)

(21) Appl. No.: 18/838,770

(22) PCT Filed: Sep. 19, 2023
(86) PCT No.: PCT/CN2023/119611

§ 371 Date: Aug. 15, 2024

(51) Int. Cl. H10K 59/80

(52) U.S. Cl. CPC H10K 59/873

(57) ABSTRACT

This disclosure provides an array substrate and a display device, the array substrate including a substrate comprising a cutting track region and a non-cutting track region, the non-cutting track region comprising a display region; a filling layer located on the substrate and arranged within the cutting track region; a functional layer located on the substrate and arranged within the non-cutting track region; and an evaporation layer comprising a first evaporation layer and a second evaporation layer separated from each other. A first distance between an upper surface of the filling layer and an upper surface of the substrate is substantially equal to a second distance between an upper surface of the functional layer and the upper surface of the substrate.

### TECHNICAL FIELD

This disclosure relates to the field of display technology, in particular, to an array substrate and a display device.

### BACKGROUND

Organic light emitting diode (OLED) display devices are more and more widely applied in display fields such as mobile phones, tablet computers, digital cameras and so on due to its advantages of thin thickness, light weight, wide viewing angle, self-luminescence, continuously adjustable luminescence color, low cost, fast response, low energy consumption, low driving voltage, wide working temperature range, simple production process, high luminescence efficiency, flexible display and the like.

### SUMMARY

According to an aspect of this disclosure, an array substrate is provided. The array substrate comprises: a substrate comprising a cutting track region and a non-cutting track region, the non-cutting track region comprising a display region; a filling layer located on the substrate and arranged within the cutting track region, the filling layer at least comprising a layer different from a film layer of the display region; a functional layer located on the substrate and arranged within the non-cutting track region; and an evaporation layer comprising a first evaporation layer and a second evaporation layer separated from each other, the first evaporation layer being located within the cutting track region, and the second evaporation layer being located within the non-cutting track region. The first evaporation layer is located on a side of the filling layer facing away from the substrate and is in contact with the filling layer, and the second evaporation layer is located on a side of the functional layer facing away from the substrate and is in contact with the functional layer, and a distance between a surface of the filling layer facing away from the substrate and a surface of the substrate facing the filling layer is a first distance, and a distance between a surface of the functional layer facing away from the substrate and a surface of the substrate facing the filling layer is a second distance, the first distance is substantially equal to the second distance.

In some embodiments, the cutting track region comprises a test region separated from the non-cutting track region, and the filling layer and the first evaporation layer are located within the test region.

In some embodiments, the array substrate further comprises an insulating layer, wherein the insulating layer is located within the non-cutting track region and arranged between the substrate and the functional layer, and the insulating layer is separated from the filling layer.

In some embodiments, a gap area between the insulating layer and the filling layer is filled with an encapsulation material, and the encapsulation material is in contact with both an edge of the filling layer and an edge of the insulating layer.

In some embodiments, a distance between the insulating layer and the filling layer is greater than or equal to 200 nm.

In some embodiments, the insulating layer comprises at least two layers stacked up, and edges of the at least two layers facing the filling layer are at different distances from the filling layer.

In some embodiments, the filling layer comprises a first filling layer and a second filling layer stacked up, the first filling layer is located between the substrate and the first evaporation layer, the second filling layer is located between the first filling layer and the first evaporation layer, and a distance between a surface of the second filling layer facing away from the substrate and the surface of the substrate facing the first filling layer is the first distance. In some embodiments, an orthogonal projection of the first evaporation layer on the substrate falls in an orthogonal projection of the second filling layer on the substrate.

In some embodiments, the first filling layer comprises a first edge and a second edge opposite each other, and the second filling layer comprises a third edge and a fourth edge opposite each other, and the first edge is closer to the non-cutting track region than the second edge, and the third edge is closer to the non-cutting track region than the fourth edge, and an orthogonal projection of the third edge on the substrate falls within an orthogonal projection of the first edge on the substrate.

In some embodiments, the first evaporation layer comprises a main body part, a first shadow part and a second shadow part, wherein the first shadow part is adjacent to the second shadow part and located between the main body part and the second shadow part, and thicknesses of the first shadow part and the second shadow part are both smaller than a thickness of the main body part.

In some embodiments, a distance between an orthogonal projection of a boundary between the first shadow part and the second shadow part on the substrate and an orthogonal projection of a first edge of the first filling layer on the substrate is greater than or equal to a length of the second shadow part in a first direction.

In some embodiments, the main body of the first evaporation layer comprises a fifth edge, and the fifth edge is substantially aligned with the fourth edge of the second filling layer, and a distance d4 from the fifth edge to a boundary between the first shadow part and the second shadow part satisfies

$$d 4 \geq \frac{a + 2 \times b - c}{2} - e ,$$

where a is a length of a sampling region of the first evaporation layer in a first direction, b is a length of the first shadow part in the first direction, c is a width of a cutting wheel, and e is a cutting precision.

In some embodiments, W1≥W2+2×W3, where W1 is a width of the first evaporation layer in a second direction, W2 is a width of a sampling region of the first evaporation layer in the second direction, W3 is a width of the first shadow part in the second direction, the second direction and the first direction is in the same plane and perpendicular to the first direction.

In some embodiments, an area of an orthogonal projection of the main body part of the first evaporation layer on the substrate is greater than a sum of areas of orthogonal projections of the first shadow part and the second shadow part on the substrate.

In some embodiments, the first filling layer comprises at least two layers stacked up, and edges of the at least two layers facing the non-cutting track region are at different distances from the non-cutting track region.

In some embodiments, a thickness of the first filling layer is greater than a thickness of the second filling layer.

In some embodiments, a material of the first filling layer comprises an organic material, and a material of the second filling layer comprises an inorganic material.

In some embodiments, the filling layer is a single layer.

In some embodiments, an orthogonal projection of the first evaporation layer on the substrate comprises a shape selected from a group consisting of a square, a rectangle, a circle and a polygon.

In some embodiments, the evaporation layer comprises an organic light-emitting layer, and the functional layer comprises an anode of an organic light-emitting diode device.

In some embodiments, the array substrate further comprises: a cathode located on a side of the second evaporation layer facing away from the substrate and located within the non-cutting track region; and an encapsulation layer located on a side of the cathode facing away from the substrate, and located within both the cutting track region and the non-cutting track region, and filling a gap area between the cathode and the filling layer.

According to another aspect of this disclosure, a display device is provided, comprising the array substrate described in any of the above embodiments.

### BRIEF DESCRIPTION OF DRAWINGS

Exemplary embodiments of this disclosure will be described in detail with reference to the drawings, in which:

FIG. 1 shows a structural diagram of an array substrate;

FIG. 2 shows a mismatch test curve for two film layers located in different regions of FIG. 1;

FIG. 3 shows a top view of a wafer comprising several array substrates according to an embodiment of this disclosure;

FIG. 4 shows a section view of a partial structure of an array substrate according to an embodiment of this disclosure;

FIG. 5 shows a mismatch test curve for two film layers located in different regions of FIG. 4;

FIG. 6 shows an enlarged view of the first evaporation layer of FIG. 4;

FIG. 7 shows a principle diagram for illustrating an evaporation shadow formed during the preparation of an evaporation layer using a mask plate;

FIG. 8 shows a section view of a partial structure of another array substrate according to an embodiment of this disclosure;

FIG. 9 shows a section view of a partial structure of yet another array substrate according to an embodiment of this disclosure; and

FIG. 10 shows a structural diagram of a display device according to an embodiment of this disclosure.

It should be understood that the drawings are only schematic views of exemplary embodiments of this disclosure rather than limitations to this disclosure, and hence are not necessarily drawn to scale. Besides, in the drawings, same or similar parts are indicated by same or similar reference signs.

### DETAILED DESCRIPTION OF EMBODIMENTS

Technical solutions in the embodiments of this disclosure will be described clearly with reference to the drawings for the embodiments. Apparently, the described embodiments are only part of possible embodiments of this disclosure rather than all of them. Based on the embodiments herein, other embodiments that can be obtained by a person having ordinary skills in the art without creative efforts all fall within the protection scope of this application.

Prior to formal description of the technical solutions of the embodiments, terms used in the embodiments will be explained and defined as follows so as to help those skilled in the art understand the technical solutions of the embodiments of this disclosure more clearly.

As used herein, a term such as “height of layer A” refers to the height of layer A relative to a substrate, the layer A is arranged on the substrate. Specifically, “height of layer A” means a distance between a surface of layer A facing away from the substrate and a surface of the substrate facing layer A.

As used herein, a term such as “distance A substantially equals distance B” or “thickness A substantially equals thickness B” means that a difference between distance A and distance B or a difference between thickness A and thickness B should consider deviations caused by factors such as manufacturing techniques and/or tolerances. For example, the difference between distance A and distance B or the difference between thickness A and thickness B may fall within a certain threshold range.

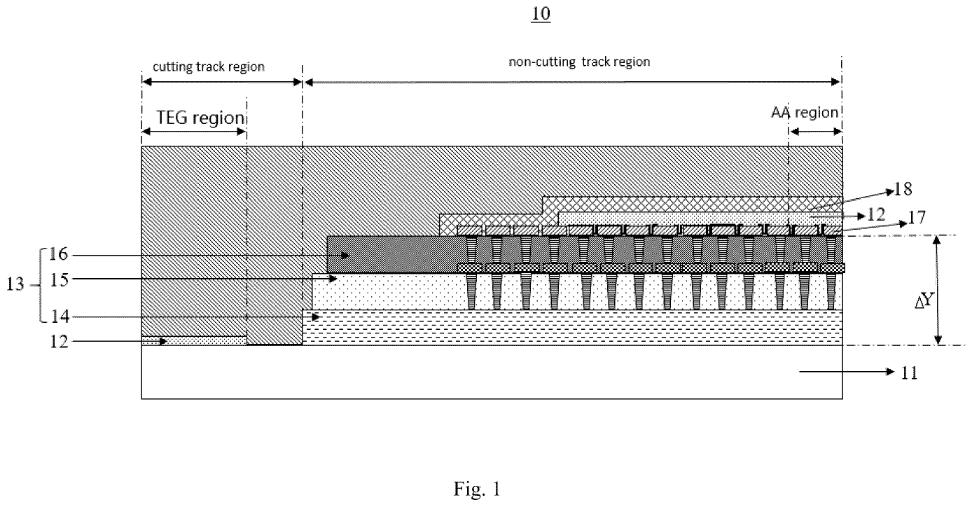

FIG. 1 shows a structural diagram of an array substrate 10 in related arts. As shown in FIG. 1, the array substrate 10 comprises a substrate 11, an organic light-emitting layer 12, an insulating layer 13, an anode 17, a cathode 18 and so on. In semiconductor chip packaging technology, chips need to be cut into multiple units, the cutting procedure is usually carried out in a cutting track region. As shown in FIG. 1, the array substrate 10 comprises a cutting track region and a non-cutting track region, the cutting track region comprises a test element group (TEG) region and the non-cutting track region comprises an AA region (or referred to as a display region). A part of the organic light-emitting layer 12 is located within the TEG region for detection of film thickness, and the other part of the organic light-emitting layer 12 is located within the non-cutting track region for emission of light. The insulating layer 13 comprises a first insulating layer 14, a second insulating layer 15 and a third insulating layer 16. Since the organic light-emitting layer 12 within the TEG region and the organic light-emitting layer 12 within the non-cutting track region are formed by the same process, the thickness of the organic light-emitting layer 12 within the non-cutting track region is usually monitored by detecting the thickness of the organic light-emitting layer 12 within the TEG region.

In the array substrate 10, a base height of the organic light-emitting layer 12 within the TEG region differs from a base height of the organic light-emitting layer 12 within the non-cutting track region considerably, and the term “a base height of the organic light-emitting layer 12” refers to a height of a film layer carrying the organic light-emitting layer 12 relative to the substrate 11. Specifically, the organic light-emitting layer 12 within the TEG region is disposed on and carried by the substrate 11, so the base height of the organic light-emitting layer 12 within the TEG region can be considered as equal to zero; the organic light-emitting layer 12 within the non-cutting track region is disposed on and carried by the anode 17, so the base height of the organic light-emitting layer 12 within the non-cutting track region refers to the height of the anode 17 relative to the substrate 11, which is approximately equal to the sum of the thickness of the first insulating layer 14, the thickness of the second insulating layer 15, the thickness of the third insulating layer 16, and the thickness of the anode 17.

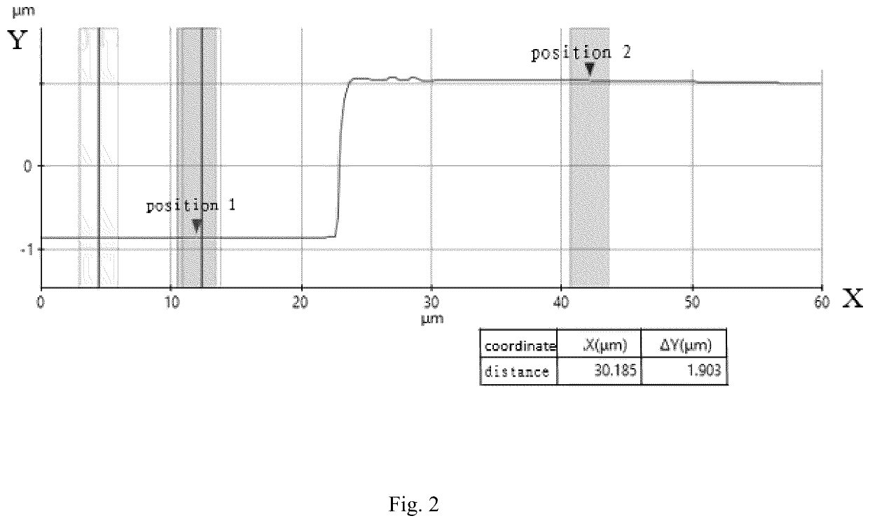

FIG. 2 shows a mismatch test curve for two film layers of FIG. 1, position 1 refers to a surface of the substrate 11 facing the organic light-emitting layer 12, and position 2 refers to a surface of the third insulating layer 16 facing away from the substrate 11, and a coordinate difference ΔX between position 1 and position 2 in an X direction is 30.185 μm, and a coordinate difference ΔY between position 1 and position 2 in a Y direction (i.e., the thickness direction of the substrate 11) is 1.903 μm. As can be known from the above, a difference between the base height of the organic light-emitting layer 12 within the TEG region and that of the organic light-emitting layer 12 within the non-cutting track region is approximately equal to the sum of ΔY and the thickness of the anode 17, i.e., the difference between the base height of the organic light-emitting layer 12 within the TEG region and the base height of the organic light-emitting layer 12 within the non-cutting track region is greater than 1.903 μm.

The organic light-emitting layer 12 within the TEG region and the organic light-emitting layer 12 within the non-cutting track region are prepared using one same mask plate, and during the preparation, the mask plate is placed opposite to the substrate 11, and an organic material is evaporated through an opening of the mask plate to a corresponding position so as to form the organic light-emitting layer 12. However, since the base height of the organic light-emitting layer 12 within the TEG region differs from the base height of the organic light-emitting layer 12 within the non-cutting track region considerably (greater than 1.903 μm), the distance of the opening of the mask plate from the substrate 11 in the TEG region is much greater than the distance of the opening of the mask plate from the anode 17 in the non-cutting track region. As is known by those skilled in the art, due to the evaporation shadow effect, the farther away the opening of the mask plate is from the position where the evaporation layer is to be formed, the more uneven the thickness of the formed film layer is. Therefore, as compared with the organic light-emitting layer 12 formed within the non-cutting track region, the organic light-emitting layer 12 formed within the TEG region has a poorer thickness uniformity, so the thickness of the organic light-emitting layer 12 within the TEG region can no longer represent the thickness of the organic light-emitting layer 12 within the non-cutting track region. Therefore, the thickness of the organic light-emitting layer 12 within the non-cutting track region cannot be monitored by detecting the thickness of the organic light-emitting layer 12 within the TEG region, which leads to a monitoring failure of the thickness of the organic light-emitting layer 12 within the non-cutting track region.

To this end, an array substrate is provided in an embodiment of this disclosure, the array substrate comprising: a substrate comprising a cutting track region and a non-cutting track region, the non-cutting track region comprising a display region; a filling layer located on the substrate and arranged within the cutting track region, the filling layer at least comprising a layer different from a film layer of the display region; a functional layer located on the substrate and arranged within the non-cutting track region; and an evaporation layer comprising a first evaporation layer and a second evaporation layer separated from each other, the first evaporation layer being arranged within the cutting track region, and the second evaporation layer being arranged within the non-cutting track region. The first evaporation layer is located on a side of the filling layer facing away from the substrate and is in contact with the filling layer, and the second evaporation layer is located on a side of the functional layer facing away from the substrate and is in contact with the functional layer, the distance between a surface of the filling layer facing away from the substrate and a surface of the substrate facing the filling layer is a first distance, and the distance between a surface of the functional layer facing away from the substrate and a surface of the substrate facing the filling layer is a second distance, the first distance being substantially equal to the second distance. For example, in consideration of deviations caused by factors such as manufacturing techniques and/or tolerances, a difference between the first distance and the second distance may fall within a certain threshold range, the threshold may be, for example, ±10 nm, ±9 nm, ±8 nm or the like, and substantially negligible.

The filling layer may be a single layer, or it may also comprise a plurality of layers. It should be noted that the expression of “the filling layer at least comprising a layer different from a film layer of the display region” means that at least one layer of the filling layer is arranged only in the cutting track region but not in the display region, and each film layer comprised in the display region is different from the at least one layer.

By arranging the filling layer in the cutting track region, the first distance between the surface of the filling layer facing away from the substrate and the surface of the substrate facing the filling layer and the second distance between the surface of the functional layer facing away from the substrate and the surface of the substrate facing the filling layer are made substantially equal. During the preparation of the evaporation layer with a mask plate, the mask plate is arranged on a side of the filling layer and the functional layer facing away from the substrate, and an organic material is evaporated through an opening of the mask plate to a corresponding position so as to form a first evaporation layer and a second evaporation layer. Since the first distance is substantially equal to the second distance, the distance of the opening of the mask plate from the filling layer is substantially equal to the distance of the opening of the mask plate from the functional layer, and thus the first evaporation layer formed in the cutting track region and the second evaporation layer formed in the non-cutting track region have substantially the same thickness, i.e., the thickness of the first evaporation layer can represent the thickness of the second evaporation layer. Therefore, the thickness of the first evaporation layer detected by a test instrument may represent the thickness of the second evaporation layer so as to effectively monitor the thickness of the second evaporation layer in the non-cutting track region, which greatly improves the monitorability of the thickness of the second evaporation layer during the preparation.

Structures of several different array substrates provided in each embodiment of this disclosure will be described in detail by means of drawings.

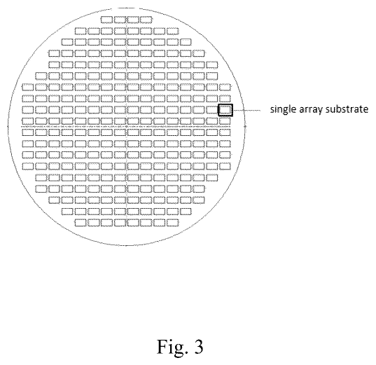

FIG. 3 shows a top view of a wafer. On the wafer, a plurality of array substrates are formed in arrays, each rectangle represents an array substrate. By cutting the wafer according to a preset cutting line, a plurality of mutually 5 independent array substrates can be obtained.

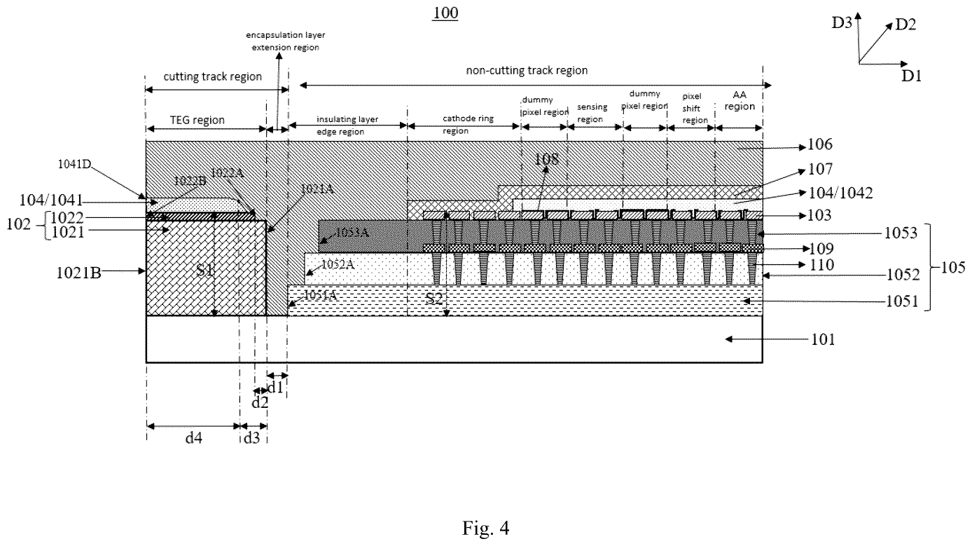

FIG. 4 shows a section view of a partial structure of an array substrate 100 according to an embodiment of the disclosure. As shown in FIG. 4, the array substrate 100 comprises: a substrate 101 comprising a cutting track region and a non-cutting track region, the non-cutting track region comprising a display region (or referred to as AA region); a filling layer 102 located on the substrate 101 and arranged within the cutting track region; a functional layer 103 located on the substrate 101 and arranged within the non-cutting track region; and an evaporation layer 104 comprising a first evaporation layer 1041 and a second 5 evaporation layer 1042 separated from each other, the first evaporation layer 1041 being located within the cutting track region, and the second evaporation layer 1042 being located within the non-cutting track region, and the thickness of the second evaporation layer 1042 within the non-cutting track region is monitored by detecting the thickness of the first evaporation layer 1041 within the cutting track region. The first evaporation layer 1041 is located on a side of the filling layer 102 facing away from the substrate 101 and is in contact with the filling layer 102, and the second evaporation layer 1042 is located on a side of the functional layer 103 facing away from the substrate 101 and is in contact with the functional layer 103, the distance between a surface of the filling layer 102 facing away from the substrate 101 and a surface of the substrate 101 facing the filling layer 102 is a first distance S1, and the distance between a surface of the functional layer 103 facing away from the substrate 101 and a surface of the substrate 101 facing the filling layer 102 is a second distance S2, the first distance S1 being substantially equal to the second distance S2. For example, in consideration of deviations caused by factors such as manufacturing techniques and/or tolerances, a difference between the first distance S1 and the second distance S2 may fall within a certain threshold range, and the threshold may be, for example, ±10 nm, ±9 nm, ±8 nm or the like, and basically negligible.

By arranging the filling layer 102 in the cutting track region, the first distance S1 and the second distance S2 can be made substantially equal, which ensures that a base height (i.e., the height of the filling layer 102 relative to the substrate 101) of the first evaporation layer 1041 is substantially equal to a base height (i.e., the height of the functional layer 103 relative to the substrate 101) of the second evaporation layer 1042 in a thickness direction D3 along the substrate 101. In this way, during the preparation of the evaporation layer 104 with a mask plate, the distance of the opening of the mask plate from the filling layer 102 is substantially equal to the distance of the opening of the mask plate from the functional layer 103, so the thickness of the first evaporation layer 1041 formed in the cutting track region is substantially equal to the thickness of the second evaporation layer 1042 formed in the non-cutting track region, i.e., the thickness of the first evaporation layer 1041 may represent the thickness of the second evaporation layer 1042. Therefore, the thickness of the second evaporation layer 1042 may be monitored by detecting the thickness of the first evaporation layer 1041, thereby effectively monitoring the thickness of the second evaporation layer 1042 in the non-cutting track region and greatly improving the monitorability of the thickness of the second evaporation layer 1042 during the preparation.

As shown in FIG. 4, the filling layer 102 comprises a first filling layer 1021 and a second filling layer 1022 stacked up, the first filling layer 1021 is located between the substrate 101 and the first evaporation layer 1041, the second filling layer 1022 is located between the first filling layer 1021 and the first evaporation layer 1041. In case the filling layer 102 comprises a first filling layer 1021 and a second filling layer 1022 stacked up, the first distance S1 refers to the distance between a surface of the second filling layer 1022 facing away from the substrate 101 and a surface of the substrate 101 facing the first filling layer 1021. The first distance S1 is substantially equal to the second distance S2. In order to control the first distance S1 precisely, it is necessary to control the thickness of the filling layer 102 precisely. By comprising a first filling layer 1021 and a second filling layer 1022 in the filling layer 102, the thickness of the filling layer 102 depends not only on the thickness of the first filling layer 1021, but also on the thickness of the second filling layer 1022. In this way, the overall thickness value of the filling layer 102 may be rectified by adjusting the thickness of the second filling layer 1022, which helps to greatly reduce the process difficulty in precisely controlling the thickness of the first filling layer 1021.

The second filling layer 1022 is mainly used to finely adjust the overall thickness value of the filling layer 102 so as to ensure that the first distance S1 is substantially equal to the second distance S2. The second filling layer 1022 is only arranged within the cutting track region and will not extend to the display region, and each film layer of the display region is different from the second filling layer 1022.

The thickness of the first filling layer 1021 is greater than the thickness of the second filling layer 1022, and a material of the first filling layer 1021 is typically an organic material, and a material of the second filling layer 1022 is typically an inorganic material. The first filling layer 1021 substantially forms the thickness of the filling layer 102. Since a thick film layer is apt to be formed using an organic material, the material of the first filling layer 1021 is typically an organic material, and the thickness of the first filling layer 1021 is greater than the thickness of the second filling layer 1022. The major function of the second filling layer 1022 is to ensure that the first distance S1 is substantially equal to the second distance S2, and the deposition precision of an inorganic layer is usually higher than the deposition precision of an organic layer, so the material of the second filling layer 1022 is typically an inorganic material. On the other hand, with the second filling layer 1022 comprising an inorganic material, in the cutting track region, the material of the first evaporation layer 1041 comprises an organic material, and the second filling layer 1022 in contact with the first evaporation layer 1041 comprises an inorganic material; in the display region, the material of the second evaporation layer 1042 is an organic material, and the functional layer 103 in contact with the second evaporation layer 1042 comprises an inorganic material, so the environment in which the first evaporation layer 1041 is located is the same as the environment in which the second evaporation layer 1042 is located, and this further facilitates that the thickness of the first evaporation layer 1041 formed is the same as the thickness of the second evaporation layer 1042, and thus a detected value of the thickness of the first evaporation layer 1041 can represent the thickness of the second evaporation layer 1042 more accurately, and thus the reliability of thickness detection data of the first evaporation layer 1041 is further improved.

In some embodiments, the thickness of the second filling layer 1022 may be substantially equal to the thickness of the functional layer 103. This helps to further ensure that the surface of the second filling layer 1022 facing away from the substrate 101 and the surface of the functional layer 103 facing away from the substrate 101 are located at the same height in the thickness direction along the substrate 101, thereby further ensuring that the base height of the first evaporation layer 1041 is substantially equal to the base height of the second evaporation layer 1042.

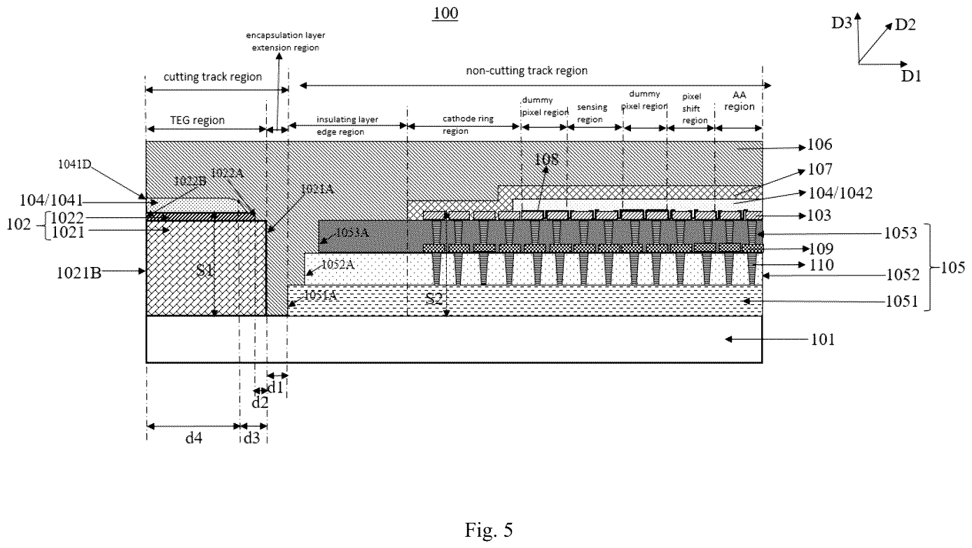

FIG. 5 shows a mismatch test curve for two film layers of FIG. 4, detection position 3 refers to a surface of the first filling layer 1021 facing away from the substrate 101, and detection position 4 refers to a surface of the third insulating layer 1053 facing away from the substrate 101, and a coordinate difference ΔX between detection position 3 and detection position 4 in an X direction is 71.053 μm, and a coordinate difference ΔY between detection position 3 and detection position 4 in a Y direction (i.e., the thickness direction of the substrate 101) is 8.033 nm. The first evaporation layer 1041 is arranged on and in direct contact with the second filling layer 1022, and the second evaporation layer 1042 is arranged on and in direct contact with the function layer 103. Since the thickness of the second filling layer 1022 is substantially equal to the thickness of the function layer 103, it can be considered that the base height of the first evaporation layer 1041 differs from the base height of the second evaporation layer 1042 by only 8.033 nm. As compared with the related art in which the difference between the base heights of the organic light-emitting layer 12 within the TEG region and the organic light-emitting layer 12 within the non-cutting track region is greater than 1.903 μm, the difference between the base heights of the first evaporation layer 1041 and the second evaporation layer 1042 is reduced significantly, and is substantially negligible. In this way, during the preparation of the evaporation layer 104 with a mask plate, the distance of the opening of the mask plate from the filling layer 1022 is substantially equal to its distance from the functional layer 103, so the first evaporation layer 1041 formed in the cutting track region and the second evaporation layer 1042 formed in the non-cutting track region have substantially the same thickness. Therefore, the thickness of the second evaporation layer 1042 may be effectively monitored by detecting the thickness of the first evaporation layer 1041, thereby greatly improving the monitorability of the thickness of the second evaporation layer 1042 during the preparation.

In some embodiments, an orthogonal projection of the first evaporation layer 1041 on the substrate 101 falls within an orthogonal projection of the second filling layer 1022 on the substrate 101, and an orthogonal projection of the second evaporation layer 1042 on the substrate 101 falls within an orthogonal projection of the functional layer 103 on the substrate 101. This can ensure that the first evaporation layer 1041 is completely disposed over the second filling layer 1022, and the second evaporation layer 1042 is completely disposed over the functional layer 103, and thus ensure that the thickness of the first evaporation layer 1041 is substantially the same as the thickness of the second evaporation layer 1042 as long as the first distance S1 between the surface of the second filling layer 1022 facing away from the substrate 101 and the surface of the substrate 101 facing the first filling layer 1021 is substantially equal to the second distance S2 between the surface of the functional layer 103 facing away from the substrate 101 and the surface of the substrate 101 facing the first filling layer 1021.

The orthogonal projection of the first evaporation 1041 on the substrate 101 may have various shapes, including but not limited to a square, a rectangle, a circle, a polygon and so on.

As shown in FIG. 4, the cutting track region comprises a TEG region (or referred to as a test region), and the first filling layer 1021, the second filling layer 1022 and the first evaporation layer 1041 are all located within the TEG region. The thickness of the second evaporation layer 1042 in the non-cutting track region is monitored by detecting the thickness of the first evaporation layer 1041 in the TEG region. The cutting track region may further comprise an encapsulation layer extension region, filled with at least a portion of an encapsulation layer 106.

Exemplarily, as shown in FIG. 4, the non-cutting track region may be divided into an AA region (or referred to as a display region), a pixel shift region, a dummy pixel region, a sensing region, a cathode ring region, an insulating layer edge region and so on. In some embodiments, the evaporation layer 104 may be an organic light-emitting layer. In case the evaporation layer 104 is an organic light-emitting layer, a portion of the second evaporation layer 1042 located in the AA region is used for emitting light so as to display images. The pixel shift region may be used as an auxiliary region for the AA region, because an optical machine for the display device is usually manually installed by professionals, which may cause some deviations in the accuracy of mechanical alignment, and the accuracy of alignment may be compensated by fine-tuning the AA region towards an adjacent pixel shift region. A portion of the second evaporation layer 1042 located in the pixel shift region may also emit light. The dummy pixel region is used to improve the homogeneity of edges of the AA region and the pixel shift region, which facilitates the overall homogeneity of the AA region. The portion of the second evaporation layer 1042 located in the dummy pixel region may not emit light. In case the evaporation layer 104 is an organic light-emitting layer, the array substrate 100 is an organic light-emitting diode (OLED) array substrate. Since the light-emitting efficiency of an OLED device at different temperatures may vary, it is necessary to monitor the temperature of the array substrate so as to regulate a pixel voltage at the AA region in real time, and the temperature of the array substrate is typically monitored in the sensing region. A portion of the second evaporation layer 1042 located in the sensing region may emit light. The functional layer 103 may be an anode of the OLED device, and in the cathode ring region, the functional layer 103 is connected with a cathode 107 so as to form a closed loop. Among the pixel shift region, the dummy pixel region, the sensing region, the cathode ring region and the insulating layer edge region, except for the sensing region, the other regions may all surround the periphery of the AA region in the form a rectangular ring. In some embodiments, the sensing region may be arranged only on opposite sides of the periphery of the AA region.

As shown in FIG. 4, the array substrate 100 may also comprise an insulating layer 105 arranged within the non-cutting track region and located between the substrate 101 and the functional layer 103, and the filling layer 102 is separated from the insulating layer 105. If the filling layer 102 is in contact with the insulating layer 105, the cutting stress will extend along the direction from the filling layer 102 to the insulating layer 105 towards the center of the AA region during cutting, thereby causing the film layer of the AA region to be peeled off. In the embodiments of this disclosure, by separating the filling layer 102 from the insulating layer 105, the transfer path of the cutting stress is broken during cutting, so the stress will not be transferred from the filling layer 102 to the insulating layer 105 and thus the film layer of the AA region will not be peeled off. The insulating layer 105 is typically an inorganic layer.

Exemplarily, a distance d1 between the filling layer 102 and the insulating layer 105 may be greater than or equal to 200 nm. The distance d1 should be a reasonable value, which may not be too great or too small. The distance d1 may not be too small because an exposure alignment accuracy during the preparation is about ±100 nm, and the distance d1 should be at least greater than or equal to the alignment accuracy so as to ensure that the filling layer 102 and the insulating layer 105 are separated from each other. The mask plate itself has a weight, and its edge region is usually provided with supporting structures while its central region is usually suspended due to the necessity of an opening region to be arranged therein. Under the effect of its gravity, the central region of the mask plate is more apt to sag, i.e., closer to the substrate 101, than the edge region, and the closer to the central region, the greater the sagging amount. Therefore, the distance d1 may not be too great. Within an allowable range of design, the smaller the distance d1 is, the closer the sagging amounts of the mask plate in the two regions are, that is, the closer the distance between the mask plate and the second filling layer 1022 in the cutting track region and the distance between the mask plate and the functional layer 103 are, and in turn, the closer the thickness of the first evaporation layer 1041 formed and the thickness of the second evaporation layer 1042 are, thereby eliminating the influence of sagging of the mask plate on the reliability of thickness monitoring of the second evaporation layer 1042.

Exemplarily, a gap area between the filling layer 102 and the insulating layer 105 is filled with an encapsulation layer 106, and the encapsulation layer 106 is in contact with both an edge of the filling layer 102 and an edge of the insulating layer 105. By filling the gap area with the encapsulation layer 106, on one hand, the separation of the filling layer 102 from the insulation layer 105 can be further ensured, and on the other hand, the encapsulation of edges of side walls of the filling layer 102 and the insulating layer 105 by the encapsulation layer 106 can be ensured, and thus the encapsulation effect can be improved.

In some embodiments, the insulating layer 105 may comprise at least two layers stacked up. By comprising several sub-layers in the insulating layer 105, the difficulty in etching each sub-layers of the insulating layer 105 can be reduced and thus the process stability can be increased. The distances of edges of the at least two layers facing the filling layer 102 from the filling layer 102 are different, i.e., the edges of the at least two layers facing the filling layer 102 are stacked in a step-like manner. For example, as shown in FIG. 4, the insulating layer 105 comprises a first insulating layer 1051, a second insulating layer 1052 and a third insulating layer 1053, the distance of an edge 1051A of the first insulating layer 1051 facing the filling layer 102 from the filling layer 102 is smaller than the distance of an edge 1052A of the second insulating layer 1052 facing the filling layer 102 from the filling layer 102, and the distance of an edge 1052A of the first insulating layer 1052 facing the filling layer 102 from the filling layer 102 is smaller than the distance of an edge 1053A of the second insulating layer 1053 facing the filling layer 102 from the filling layer 102. The step-like stacking of the edges of the first insulating layer 1051, the second insulating layer 1052 and the third insulating layer 1053 can increase the contact area of the encapsulation layer 106 with each insulating layer, thereby facilitating better encapsulation of the edges of each insulating layer by the encapsulation layer 106.

As shown in FIG. 4, the first filling layer 1021 comprises a first edge 1021A and a second edge 1021B opposite each other, and the second filling layer 1022 comprises a third edge 1022A and a fourth edge 1022B opposite each other, the first edge 1021A is closer to the non-cutting track region than the second edge 1021B, and the third edge 1022A is closer to the non-cutting track region than the fourth edge 1022B. An orthogonal projection of the third edge 1022A on the substrate 101 falls within an orthogonal projection of the first edge 1021A on the substrate 101, which can ensure that the material of the second filling layer 1022 will not fall into the encapsulation layer extension region and thus avoid affecting the encapsulation effect of the encapsulation layer 106. Exemplarily, a distance d2 between the orthogonal projection of the third edge 1022A on the substrate 101 and the orthogonal projection of the first edge 1021A on the substrate 101 may be greater than or equal to 200 nm. In some examples, an orthogonal projection of the second filling layer 1022 on the substrate 101 may fall within an orthogonal projection of the first filling layer 1021 on the substrate 101.

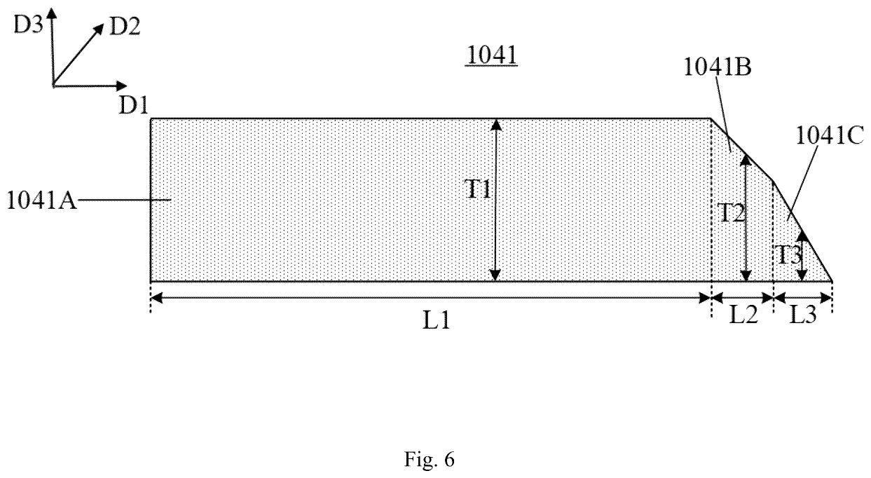

FIG. 6 shows an enlarged view of the first evaporation layer 1041 of FIG. 4. As shown in FIG. 6, the first evaporation layer 1041 comprises a main body part 1041A, a first shadow part 1041B and a second shadow part 1041C, the first shadow part 1041B is adjacent to the second shadow part 1041C, and the first shadow part 1041B is located between the main body part 1041A and the second shadow part 1041C; and thickness T2 of the first shadow part 1041B and thickness T3 of the second shadow part 1041C are both smaller than thickness T1 of the main body part 1041A.

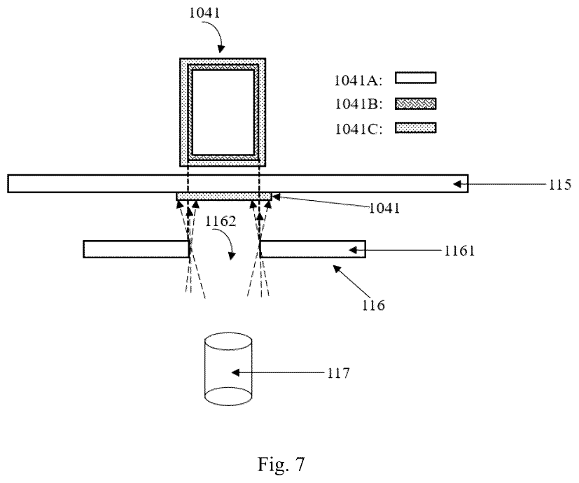

FIG. 7 shows a principle diagram illustrating an evaporation shadow formed during preparation of the evaporation layer 104 with a mask plate, and as an example, FIG. 7 only shows the first evaporation layer 1041, and it should be understood that the second evaporation layer 1042 also has a similar evaporation shadow.

As shown in FIG. 7, an organic material for forming the evaporation layer 104 is stored in an evaporation source 117. A mask plate 116 comprises a shield part 1161 and an opening region 1162, the organic material is heated at a high temperature to form gaseous molecules, which diffuse along a propagation path, and are deposited on the substrate 115 through the opening region 1162 of the mask plate 116, and form the first evaporation layer 1041 in the TEG region of the substrate 115. During the evaporation, there is a certain gap between the substrate 115 and the mask plate 116, so the sublimated organic material molecules will not only form an evaporation layer at a position corresponding to the opening region 1162 of the mask plate 116, but also inevitably form an evaporation shadow in an adjacent area of the opening region 1162, which may be understood as the evaporation layer having a smaller thickness here than in the main body part. Specifically, FIG. 7 shows an enlarged plan view of the first evaporation layer 1041 above the substrate 115. As shown in FIG. 7, since there is a gap between the substrate 115 and the mask plate 116, the first evaporation layer 1041 formed on the substrate 115 comprises a main body part 1041A, a first shadow part 1041B and a second shadow part 1041C. A first orthogonal projection of the main body part 1041A on the substrate 115 falls within a second orthogonal projection of the opening region 1162 on the substrate 115, but occupies most of the area of the second orthogonal projection. The first shadow part 1041B surrounds the periphery of the main body part 1041A, and is located in a small area within the range corresponding to the opening region 1162, and also can be referred to as an evaporation inner shadow. The second shadow part 1041C surrounds the periphery of the first shadow part 1041B, and is located in a small area outside the range corresponding to the opening region 1162, and also can be referred to as an evaporation outer shadow. Due to the evaporation shadow effect, the thickness T2 of the first shadow part 1041B and the thickness T3 of the second shadow part 1041C are smaller than the thickness T1 of the main body part 1041A.

An area of an orthogonal projection of the main body part 1041A of the first evaporation layer 1041 on the substrate 101 is greater than (and typically far greater than) the sum of areas of orthogonal projections of the first shadow part 1041B and the second shadow part 1041C on the substrate 101. In this way, the thickness of the first evaporation layer 1041 detected by a test instrument is probably the thickness of the main body part 1041A instead of the thickness of the first shadow part 1041B and/or the second shadow part 1041C, thereby avoiding interference to the thickness monitoring of the second evaporation layer 1042 by the thickness of the first shadow part 1041B and/or the second shadow part 1041C.

Referring to FIG. 4 and FIG. 6, in some embodiments, a distance d3 between an orthogonal projection of a boundary between the first shadow part 1041B and the second shadow part 1041C on the substrate 101 and an orthogonal projection of a first edge 1021A of the first filling layer 1021 on the substrate 101 is greater than or equal to a length L3 of the second shadow part 1041C in a first direction D1. By making d3≥L3, it can be ensured that the first evaporation layer 1041, in particular the second shadow part 1041C of the first evaporation layer 1041, will not fall into the encapsulation layer extension region, thereby avoiding affecting the encapsulation effect of the encapsulation layer 106 in the encapsulation layer extension region. In an example, the length L3 of the second shadow part 1041C in the first direction D1 is 150 μm, thus d3≥150 μm.

Continuing to refer to FIG. 4 and FIG. 6, the main body part 1041A of the first evaporation layer 1041 comprises a fifth edge 1041D, the fifth edge 1041D is substantially aligned with the fourth edge 1022B of the second filling layer 1022 in a thickness direction of the substrate 101, and the distance from the fifth edge 1041D to the boundary between the first shadow part 1041B and the second shadow part 1041C is d4. In some embodiment, d4 satisfies inequality

$$d 4 \geq \frac{a + 2 \times b - c}{2} - e ,$$

where a is a length of a sampling region of the first evaporation layer 1041 in the first direction D1, b is a length L2 of the first shadow part 1041B in the first direction D1, c is a width of a cutting wheel, and e represents a cutting precision. The sampling region is a partial region of the main body part 1041A of the first evaporation layer 1041, and a length of the sampling region in the first direction D1 is smaller than the length L1 of the main body part 1041A in the first direction D1. By designing the value of d4, it can be ensured that the length of the sampling region of the first evaporation layer 1041 satisfies test requirements of the test instrument. In an example, a is about 200 μm, b is about 150 μm, c is about 70 μm, and e is about 15 μm, so d4≥200 μm.

A width of the first evaporation layer 1041 in a second direction D2 is W1, a width of the sampling region of the first evaporation layer 1041 in the second direction D2 is W2, a width of the first shadow part 1041B of the first evaporation layer 1041 in the second direction D2 is W3, the second direction D2 is located in the same plane as the first direction D1 and perpendicular to the first direction D1, and it can be seen from the figure that the second direction D2 is a direction perpendicular to the plane of the paper. In some embodiments, W1, W2 and W3 satisfy W1≥W2+2×W3, thereby ensuring the width of the sampling region of the first evaporation layer 1041 satisfies test requirements of the test instrument. The sampling region is a partial region of the main body part 1041A of the first evaporation layer 1041, and the width W2 of the sampling region in the second direction D2 is smaller than the width of the main body part 1041A in the second direction D2. In an example, the value of W2 is about 200 μm, and the value of W3 is about 150 μm, so W1≥500 μm.

The thickness of the second evaporation layer 1042 in the non-cutting track region is monitored by detecting the thickness of the first evaporation layer 1041 in the TEG region with a test instrument. The test instrument can be a probe for example. The probe has a certain contact area, and the area of the sampling region of the first evaporation layer 1041 should be greater than or equal to the contact area of the probe. For example, the length of the sampling region of the first evaporation layer 1041 may be 200 μm, and the width of the sampling region of the first evaporation layer 1041 may be 200 μm.

In the array substrate 100 described above, the evaporation layer 104 may be any suitable film layer and is formed through an evaporation process using a mask plate. In an example, the evaporation layer 104 may be an organic light-emitting layer of an OLED device, and in this case, the functional layer 103 is an anode of the OLED device.

As shown in FIG. 4, the array substrate 100 may further comprise a cathode 107 and an encapsulation layer 106. The cathode 107 is located on a side of the second evaporation layer 1042 facing away from the substrate 101 and arranged within the non-cutting track region, the cathode 107 provides electrons while the functional layer (the anode) 103 provides holes, and the electrons and the holes are recombined in the second evaporation layer 1042 so as to enable the second evaporation layer 1042 to emit light. The encapsulation layer 106 is located on a side of the cathode 107 facing away from the substrate 101 and arranged within the cutting track region and the non-cutting track region, the encapsulation layer 106 covers the first evaporation layer 1041 and the cathode 107, and fills a gap region between the cathode 107 and the filling layer 102 as well as a gap region between the insulating layer 105 and the filling layer 102 so as to prevent external moisture and other substances from invading the interior of the array substrate 100.

The array substrate 100 may further comprise a pixel defining layer 108 for defining a plurality of sub-pixel regions of the array substrate 100. The array substrate 100 may further comprise an electrode layer 109 and a via 110, the via 110 may be filled with an electrically conductive material, and the functional layer 103 is connected with the electrode layer 109 by the via 110.

The material of the substrate 101 may be various suitable types of materials, including but not limited to an organic material, an inorganic material, a flexible material, a rigid material and so on. Exemplarily, the substrate 101 may be a silicon substrate, and in this case, the array substrate 100 is a silicon-based organic light-emitting diode array substrate. A silicon-based organic light-emitting diode array substrate has advantages such as small volume, high resolution and so on, and can be widely applied in conventional display devices (e.g., cell phones, televisions and computers), near-eye display devices (e.g., Virtual Reality (VR)), Augmented Reality (AR) and the like.

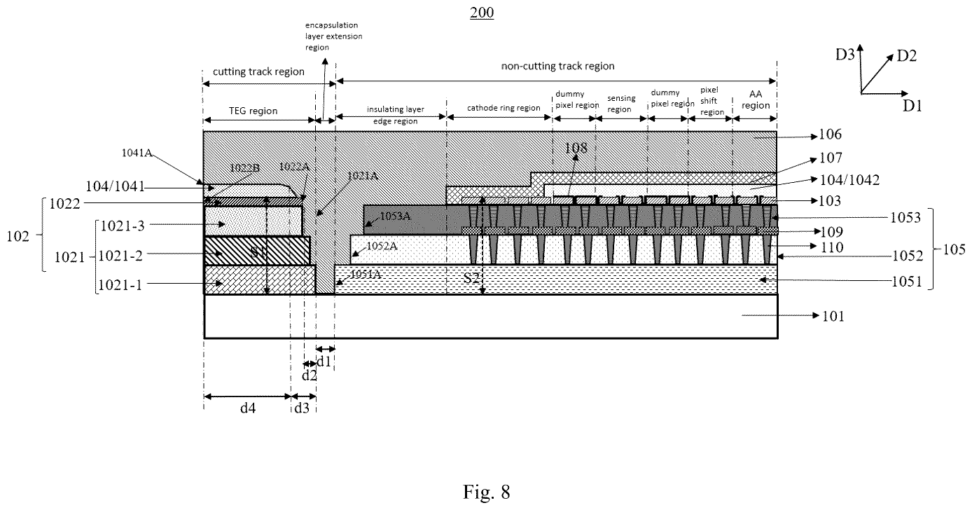

FIG. 8 shows a section view of a partial structure of an array substrate 200. The array substrate 200 has substantially the same structure as the array substrate 100, and hence the same parts are indicated with the same reference signs. Therefore, explanations for FIG. 4 may be referred to for detailed roles and functions of parts in FIG. 8 having the same reference signs as those in FIG. 4, which will not be repeated herein for simplicity. For the sake of brevity, only differences between the array substrate 200 and the array substrate 100 will be introduced below.

In the array substrate 100, the first filling layer 1021 is a single layer. In contrast with the array substrate 100, the first filling layer 1021 of the array substrate 200 comprises at least two layers stacked up. By comprising several sub-layers in the first filling layer 1021, the difficulty in etching each sub-layers of the first filling layer 1021 can be reduced and thus the process stability can be increased. For example, as shown in FIG. 8, the first filling layer 1021 comprises a first sub-layer 1021-1, a second sub-layer 1021-2 and a third sub-layer 1021-3 stacked up.

In some embodiments, the thickness of the first sub-layer 1021-1 is substantially the same as the thickness of the first insulating layer 1051, the thickness of the second sub-layer 1021-2 is substantially the same as the thickness of the second insulating layer 1052, and the thickness of the third sub-layer 1021-3 is substantially the same as the thickness of the third insulating layer 1053. Besides, the thickness of the second filling layer 1022 is substantially the same as the thickness of the functional layer 103, which can further ensure the first distance S1 is substantially equal to the second distance S2, and in turn further ensure the thickness of the first evaporation layer 1041 formed in the cutting track region is substantially the same as the thickness of the second evaporation layer 1042 formed in the non-cutting track region. In some embodiments, the first distance S1 differs from the second distance S2 only by 8.033 nm, which is substantially negligible. In this way, it can be ensured that the thickness of the first evaporation layer 1041 formed in the cutting track region is substantially the same as the thickness of the second evaporation layer 1042 formed in the non-cutting track region, and thus the thickness of the second evaporation layer 1042 is monitored by detecting the thickness of the first evaporation layer 1041, and effective monitoring of the thickness of the second evaporation layer 1042 is achieved.

In some embodiments, as shown in FIG. 8, distances of edges of the first sub-layer 1021-1, the second sub-layer 1021-2 and the third sub-layer 1021-3 facing the non-cutting track region from the non-cutting track region vary from each other, i.e., the edges of the first sub-layer 1021-1, the second sub-layer 1021-2 and the third sub-layer 1021-3 facing the non-cutting track region are stacked in a step-like manner. Such a design can increase the contact area of the encapsulation layer 106 with the first sub-layer 1021-1, the second sub-layer 1021-2 and the third sub-layer 1021-3, thereby facilitating improvement of the encapsulation effect.

The technical effects of the array substrate 100 may be referred to for other technical effects of the array substrate 200, and for the sake of brevity, similarities between the technical effects of the array substrate 200 and the array substrate 100 will not be repeated herein.

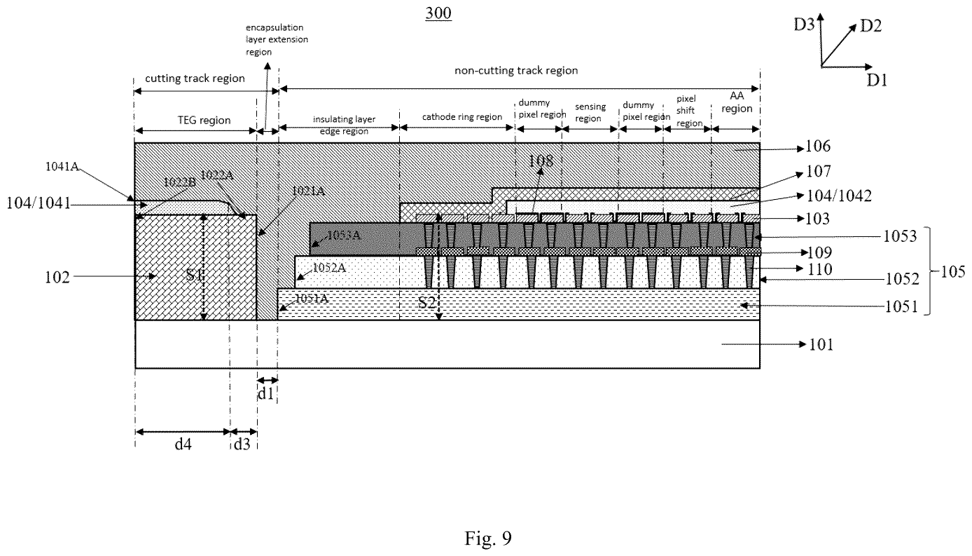

FIG. 9 shows a section view of a partial structure of an array substrate 300. The array substrate 300 has substantially the same structure as the array substrate 100, and hence the same parts are indicated by the same reference signs. Therefore, explanations for FIG. 4 may be referred to for detailed roles and functions of parts in FIG. 9 having the same reference signs as those in FIG. 4, which will not be repeated herein for simplicity. For the sake of brevity, only differences between the array substrate 300 and the array substrate 100 will be introduced below.

In the array substrate 100, the filling layer 102 comprises a first filling layer 1021 and a second filling layer 1022. In contrast with the array substrate 100, in the array substrate 300, the filling layer 102 is a single layer. By designing the filling layer 102 as a single layer, it is possible to form the filling layer 102 by only one patterning process during the preparation, which makes the preparation process simpler.

The distance between a surface of the filling layer 102 facing away from the substrate 101 and a surface of the substrate 101 facing the filling layer 102 is a first distance S1, and the distance between a surface of the functional layer 103 facing away from the substrate 101 and a surface of the substrate 101 facing the filling layer 102 is a second distance S2, the first distance S1 being substantially equal to the second distance S2. In some embodiments, the first distance S1 differs from the second distance S2 only by 8.033 nm, which is substantially negligible. In this way, it can be ensured that the thickness of the first evaporation layer 1041 formed in the cutting track region is substantially the same as the thickness of the second evaporation layer 1042 formed in the non-cutting track region, and thus the thickness of the second evaporation layer 1042 can be monitored by detecting the thickness of the first evaporation layer 1041, and thus effective monitoring of the thickness of the second evaporation layer 1042 can be achieved.

The technical effects of the array substrate 100 may be referred to for other technical effects of the array substrate 300, and for the sake of brevity, similarities between the technical effects of the array substrate 300 and the array substrate 100 will not be repeated herein.

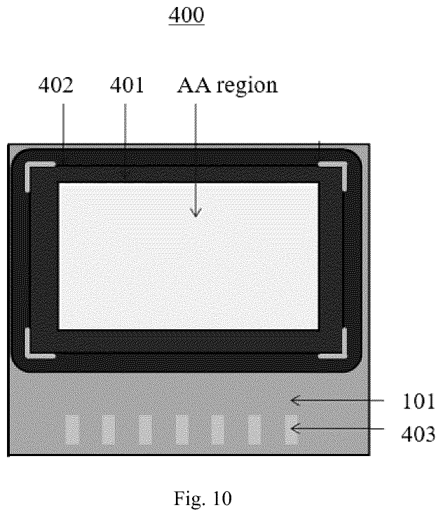

FIG. 10 shows a display device 400 according to an embodiment of this disclosure, and the display device 400 may comprise any of the array substrates 100, 200 and 300 described above.

As shown in FIG. 10, the display device 400 comprises a substrate 101, a cover plate 401 disposed opposite the substrate 101 and a bezel 402 disposed around an AA region. The display device 400 further comprises in the non-display region a plurality of bonding electrodes 403 for connecting with devices such as a flexible circuit board.

The display device 400 may be various suitable types of display devices, including but not limited to mobile phones, tablets, televisions, monitors, laptops, digital photo frames, navigators, near-eye display devices such as VR or AR, etc.

The technical effects of the array substrates described in the above embodiments may be referred to for the technical effects of the display device 400, which, for the sake of brevity, will not be repeated herein.

It should be understood that although terms of first, second, third and so on may be used to described various elements, parts, regions, layers and/or portions herein, the elements, parts, regions, layers and/or portions should not be limited by these terms. These terms are only used to distinguish one element, part, region, layer or portion from another element, part, region, layer or portion. Therefore, the first element, part, region, layer or portion discussed above may also be referred to as a second element, part, region, layer or portion without departing from the teachings of this disclosure.

Spatially relative terms such as “row”, “column”, “below”, “above”, “left”, “right” and so on may be used herein for the convenience of description of relations between one element or feature as shown in the figures and another element or feature. It will be understood that these spatially relative terms are intended to cover different orientations of a device in use or operation other than the orientations described in the figures. For example, if the device in the figures is flipped over, an element described as “below another element or feature” will be oriented as “above another element or feature”. Therefore, the exemplary term “below” may cover orientations of both “above” and “below”. The device may be oriented in other manners (e.g., rotated by 90 degrees or oriented otherwise) and correspondingly interpret the spatially relative descriptors used herein. Furthermore, it will also be understood that when a layer is referred to as “being between two layers”, it may be a unique layer between the two layers, or there can be also one or more intermediate layers.

The terms used herein are only used for describing specific embodiments instead of limiting this disclosure. As used herein, the singular form “one”, “a/an” and “the” are also intended to include a plural form, unless indicated otherwise in the context. It will be further understood that when used herein the term “comprise” and/or “include” indicates the existence of the described features, wholes, steps, operations, elements and/or components, but does not exclude the existence or addition of one or more other features, wholes, steps, operations, elements, components and/or a combination thereof. As used herein, the term “comprise” and/or “include” any and all combinations of one or more of the associated listed items. Depictions with reference to “one embodiment”, “another embodiment” and so on throughout this description, mean that a specific feature, structure, material, or characteristic described in combination with the embodiment is included in at least one embodiment of this disclosure. Schematic expressions of the above terms herein are not necessarily directed at the same embodiments or examples. Besides, the specific feature, structure, material, or characteristic may be combined in any one or more embodiments or examples in a suitable manner. In addition, wherein no contradictions are involved, a person skilled in the art may combine different embodiments or examples described herein and features of different embodiments or examples.

It should be understood that when an element or a layer is referred to as “located on another element or layer”, “connected to another element or layer”, “coupled to another element or layer” or “adjacent to another element or layer”, it may be located on another element or layer, connected to another element or layer, coupled to another element or layer or adjacent to another element or layer directly, or there may be an intermediate element or layer. In contrast, when an element is referred to as “located on another element or layer directly”, “connected to another element or layer directly”, “coupled to another element or layer directly” or “adjacent to another element or layer directly”, there is no intermediate element or layer. However, in no case should “on” or “directly on” be construed as requiring that one layer completely covers an underlying layer.

The embodiments of this disclosure are described herein with reference to schematic illustrations (and intermediate structures) of ideal embodiments of this disclosure. For this reason, changes in the illustrated shapes should be expected, e.g., as a result of manufacturing techniques and/or tolerances. Therefore, the embodiments of this disclosure should not be construed as being limited to the particular shapes of regions illustrated herein, but instead, they should comprise deviations of the shapes caused by manufacture for instance. Therefore, the regions illustrated in the drawings are essentially schematic, and their shapes are not intended to illustrate the actual shape of the regions of the device or limit the scope of this disclosure.

Unless otherwise defined, terms (including technical terms and scientific terms) used herein have the same meanings as usually understood by a person having ordinary skills in the art of this disclosure. It will be further understood that terms such as those defined in commonly used dictionaries should be construed as having a meaning that is consistent with their meaning in the relevant art and/or in the context herein, and will not be construed in an idealized or overly formal sense unless explicitly defined so herein.

The description above is only specific embodiments of this disclosure, but the protection scope of this disclosure is not limited thereto. Any modification or substitution easily conceivable for a skilled person who is familiar with this art within the technical scope of this disclosure shall fall within the protection scope of this disclosure. Therefore, the protection scope of this disclosure should be subject to the protection scope of the claims.

1. An array substrate, comprising:
a substrate comprising a cutting track region and a non-cutting track region, the non-cutting track region comprising a display region;
a filling layer located on the substrate and arranged within the cutting track region, the filling layer at least comprising a layer different from a film layer of the display region;
a functional layer located on the substrate and arranged within the non-cutting track region; and
an evaporation layer comprising a first evaporation layer and a second evaporation layer separated from each other, the first evaporation layer being located within the cutting track region, and the second evaporation layer being located within the non-cutting track region,
wherein the first evaporation layer is located on a side of the filling layer facing away from the substrate and is in contact with the filling layer, and the second evaporation layer is located on a side of the functional layer facing away from the substrate and is in contact with the functional layer, and a distance between a surface of the filling layer facing away from the substrate and a surface of the substrate facing the filling layer is a first distance, and a distance between a surface of the functional layer facing away from the substrate and a surface of the substrate facing the filling layer is a second distance, the first distance is substantially equal to the second distance.

2. The array substrate according to claim 1, wherein the cutting track region comprises a test region separated from the non-cutting track region, and the filling layer and the first evaporation layer are located within the test region.

3. The array substrate according to claim 1, the array substrate further comprises an insulating layer, wherein the insulating layer is located within the non-cutting track region and arranged between the substrate and the functional layer, and the insulating layer is separated from the filling layer.

4. The array substrate according to claim 3, wherein a gap area between the insulating layer and the filling layer includes an encapsulation material, and the encapsulation material is in contact with both an edge of the filling layer and an edge of the insulating layer.

5. (canceled)

6. The array substrate according to claim 3, wherein the insulating layer comprises at least two layers stacked up, and edges of the at least two layers facing the filling layer are at different distances from the filling layer.

7. The array substrate according to claim 1, wherein the filling layer comprises a first filling layer and a second filling layer stacked up, the first filling layer is located between the substrate and the first evaporation layer, the second filling layer is located between the first filling layer and the first evaporation layer, and a distance between a surface of the second filling layer facing away from the substrate and the surface of the substrate facing the first filling layer is the first distance.

8. The array substrate according to claim 7, wherein an orthogonal projection of the first evaporation layer on the substrate falls in an orthogonal projection of the second filling layer on the substrate.

9. The array substrate according to claim 7, wherein the first filling layer comprises a first edge and a second edge opposite each other, and the second filling layer comprises a third edge and a fourth edge opposite each other, and the first edge is closer to the non-cutting track region than the second edge, and the third edge is closer to the non-cutting track region than the fourth edge, and an orthogonal projection of the third edge on the substrate falls within an orthogonal projection of the first edge on the substrate.

10. The array substrate according to claim 9, wherein the first evaporation layer comprises a main body part, a first shadow part and a second shadow part, wherein the first shadow part is adjacent to the second shadow part and located between the main body part and the second shadow part, and thicknesses of the first shadow part and the second shadow part are both smaller than a thickness of the main body part.

11. The array substrate according to claim 10, wherein a distance between an orthogonal projection of a boundary between the first shadow part and the second shadow part on the substrate and an orthogonal projection of a first edge of the first filling layer on the substrate is greater than or equal to a length of the second shadow part in a first direction.

12. The array substrate according to claim 10, wherein the main body part of the first evaporation layer comprises a fifth edge, and the fifth edge is substantially aligned with the fourth edge of the second filling layer, and a distance d4 from the fifth edge to a boundary between the first shadow part and the second shadow part satisfies
$$d 4 \geq \frac{a + 2 \times b - c}{2} - e ,$$
wherein a is a length of a sampling region of the first evaporation layer in a first direction, b is a length of the first shadow part in the first direction, c is a width of a cutting wheel, and e is a cutting precision.

13. The array substrate according to claim 11, wherein,
$$W 1 \geq W 2 + 2 \times W 3 ,$$
wherein W1 is a width of the first evaporation layer in a second direction, W2 is a width of a sampling region of the first evaporation layer in the second direction, W3 is a width of the first shadow part in the second direction, the second direction and the first direction are in a same plane and perpendicular to the first direction.

14. The array substrate according to claim 10, wherein an area of an orthogonal projection of the main body part of the first evaporation layer on the substrate is greater than a sum of areas of orthogonal projections of the first shadow part and the second shadow part on the substrate.

15. The array substrate according to claim 7, wherein the first filling layer comprises at least two layers stacked up, and edges of the at least two layers facing the non-cutting track region are at different distances from the non-cutting track region.

16. The array substrate according to claim 7, wherein a thickness of the first filling layer is greater than a thickness of the second filling layer.

17. The array substrate according to claim 7, wherein a material of the first filling layer comprises an organic material, and a material of the second filling layer comprises an inorganic material.

18. The array substrate according to claim 1, wherein the filling layer is a single layer.

19. (canceled)

20. The array substrate according to claim 1, wherein the evaporation layer comprises an organic light-emitting layer, and the functional layer comprises an anode of an organic light-emitting diode device.

21. The array substrate according to claim 20, further comprising:
a cathode located on a side of the second evaporation layer facing away from the substrate and located within the non-cutting track region; and
an encapsulation layer located on a side of the cathode facing away from the substrate, and located within both the cutting track region and the non-cutting track region, and in a gap area between the cathode and the filling layer.

22. A display device, comprising the array substrate according to claim 1.
